(19) United States
(12) Patent Application Publication
(10) Pub. No.: US 2023/0033193 A1
(43) Pub. Date: Feb. 2, 2023

(54) WATER-COOLING DEVICE FOR SOLID-STATE DISK

(71) Applicant: TEAM GROUP INC., New Taipei City (TW)

(72) Inventors: Hsun Chia MA, New Taipei City (TW); Tzu Hsien CHUANG, New Taipei City (TW); Kuan Ting CHEN, New Taipei City (TW)

(73) Assignee: TEAM GROUP INC., New Taipei City (TW)

(21) Appl. No.: 17/701,324

(22) Filed: Mar. 22, 2022

(30) Foreign Application Priority Data
Jul. 28, 2021 (TW) 110127626

(51) Int. Cl. H05K 7/20

(52) U.S. Cl. CPC H05K 7/20272; H05K 7/20263; H05K 7/20509; G06F 1/20

(57) ABSTRACT

Disclosed is a water-cooling device for a solid-state disk, comprising: a water-cooling component, including a water block and a water pump disposed in the water block, the water block being provided with a heat conducting member to form heat conduction with the solid-state disk; a first pipe; a second pipe; and a water-cooling radiator component having a heat radiator, wherein the first pipe and the second pipe are connected between the radiator and the water-cooling component, the water pump is provided to drive cooling liquid to flow in a liquid circulating sequence of the water-cooling component, the second pipe, the water-cooling radiator component, the first pipe and the water-cooling component, and the heat radiator of the water-cooling radiator component is provided to transfer heat from the cooling liquid to the air.

### FIELD OF THE INVENTION

The present invention relates to a solid-state disk, and more particularly relates to a water-cooling device for a solid-state disk.

### BACKGROUND OF THE INVENTION

With the advancement of solid-state disk technology, the speed of the solid-state disk is gradually increased. For example, an M.2 solid-state disk, which is based on the NVMe specification and uses PCIe bus, can deliver a read/write speed several times faster than ever before. However, its excellent performance also causes a problem of heat generation that cannot be ignored. A large amount of heat generated by long-term and frequent read/write processes of the solid-state disk will be concentrated in tiny controller and NAND chips, which will lead to overheating and trigger the protection mechanism, resulting in performance degradation or even shortened lifespan of the solid-state disk.

In order to solve the problem of overheating, the conventional solid-state disks adopt water cooling. A conventional water-cooling device generally has a water block, a water pump, a radiator and pipes that connect the aforementioned components. However, the conventional water-cooling device treats the solid-state disks as non-primary cooling objects as compared with other cooling objects such as CPUs and graphic cards. Accordingly, the conventional solid-state disks is only equipped with a water block for cooling liquid which passes through. Compared with CPUs and graphics cards, the heat generated by solid-state disks has reached a level that is difficult to be ignored. Therefore, it is necessary to propose a water cooling device dedicated to cooling solid-state disks.

### SUMMARY OF THE INVENTION

Accordingly, one objective of the present invention is to provide a water-cooling device, which is dedicated to cooling solid-state disks.

In order to overcome the technical problems in prior art, the present invention provides a water-cooling device for a solid-state disk, comprising: a water-cooling component, including a water block and a water pump, the water block having a water-pump accommodating space, the water pump being disposed in the water-pump accommodating space, the water block being further provided with a liquid inlet, a liquid outlet and a heat conducting member, the heat conducting member being provided to form heat conduction with the solid-state disk to enable the water block to receive heat from the solid-state disk; a first pipe, one end of the first pipe being connected to the liquid inlet; a second pipe, one end of the second pipe being connected to the liquid outlet; and a water-cooling radiator component, having a radiator inlet, a radiator outlet and a heat radiator, the radiator outlet being connected to the other end of the first pipe, and the radiator inlet being connected to the other end of the second pipe, the water pump being provided to drive cooling liquid to flow in a liquid circulating sequence of the water-cooling component, the second pipe, the water-cooling radiator component, the first pipe and the water-cooling component, the heat radiator of the water-cooling radiator component is provided to transfer heat from the cooling liquid to the air.

In one embodiment of the present invention, the water-cooling device is provided, wherein the heat conducting member includes a metal block, which is in contact with the solid-state disk so that the water block receives the heat from the solid-state disk via the metal block.

In one embodiment of the present invention, the water-cooling device is provided, wherein the heat conducting member includes a clip, the metal block has a fixing hole to which the clip is fixed, and the solid-state disk is clamped between the metal block and the clip.

In one embodiment of the present invention, the water-cooling device is provided, wherein the metal block has a groove through which the liquid of the liquid circulating sequence flows.

In one embodiment of the present invention, the water-cooling device is provided, wherein a minimum distance between the liquid inlet and the heat conducting member is less than a minimum distance between the liquid outlet and the heat conducting member.

In one embodiment of the present invention, the water-cooling device is provided, wherein the water-cooling radiator component includes a fan which faces towards the heat radiator.

By the technical means adopted by the present invention, the water cooling head and the water pump are combined into an assembly. The heat conducting member of the water block is provided to form heat conduction with the solid-state disk to enable the water block to receive heat from the solid-state disk. Preferably, the shape of the heat conducting member matches the arrangement of chips of the solid state disk so that the water-cooling device of the present invention can be dedicated to cooling the solid state disks.

### BRIEF DESCRIPTION OF THE DRAWINGS

FIG. 1 is a schematic perspective view illustrating a water-cooling device according to an embodiment of the present invention;

FIG. 2 is a schematic exploded view illustrating the water-cooling device according to the embodiment of the present invention;

FIG. 3 is a schematic partial side cross-section view illustrating the water-cooling device according to the embodiment of the present invention when mounted on a solid-state disk; and

FIG. 4 is a schematic partial side cross-section view illustrating the water-cooling device according to the embodiment of the present invention.

### DETAILED DESCRIPTION OF THE PREFERRED

### Embodiments

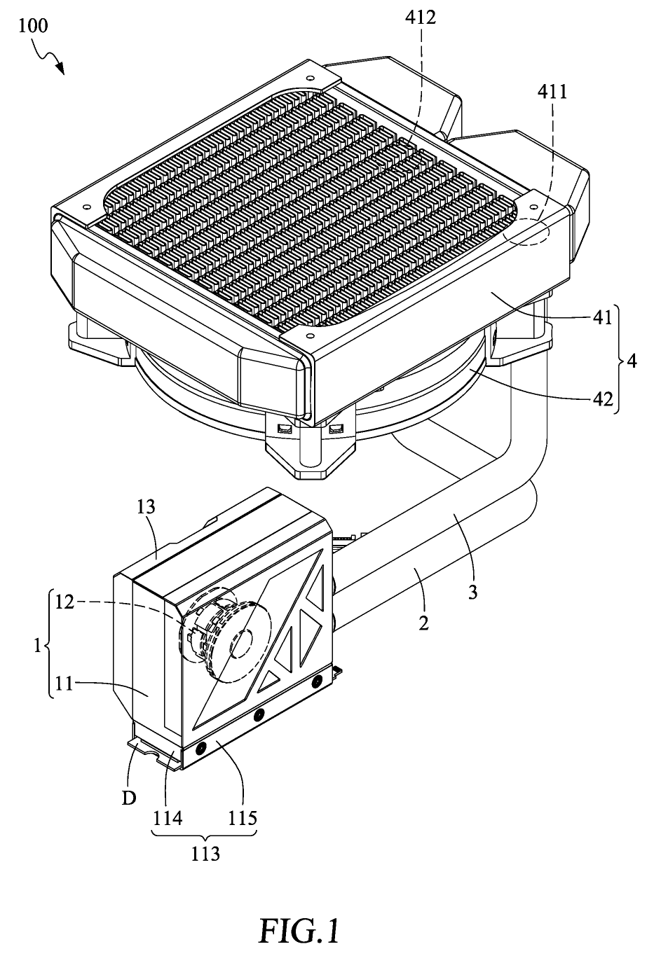

The preferred embodiments of the present invention are described in detail below with reference to FIG. 1 to FIG. 4. The description is used for explaining the embodiments of the present invention only, but not for limiting the scope of the claims.

As shown in FIG. 1, a water-cooling device 100 according to an embodiment of the present invention includes: a water-cooling component 1, a first pipe 2, a second pipe 3 and a water-cooling radiator component 4.

As shown in FIG. 1 to FIG. 3, in the water-cooling device 100 according to the embodiment of the present invention, the water-cooling component 1 includes a water block 11 and a water pump 12. The water block 11 has a water-pump accommodating space S. The water pump 12 is disposed in the water-pump accommodating space S so that the water block 11 and the water pump 12 are combined together.

The water block 11 has a liquid outlet 111, a liquid inlet 112 and a heat conducting member 113. The liquid outlet 111 and the liquid inlet 112 are respectively used for cooling liquid to flow out of and into the water block 11. The heat conducting member 113 is provided to form heat conduction with the solid-state disk D to enable the heat conducting member 113 to receive heat from the solid-state disk D, and enable the heat to be transferred to the water block 11 through the heat conducting member 113.

At least a part of the water block 11 is a light transparent material through which a user can observe the cooling liquid in the water block 11.

The water pump 12 drives the cooling liquid to flow in a liquid circulating sequence of the water-cooling component 1, the second pipe 3, the water-cooling radiator component 4, the first pipe 2 and the water-cooling component 1.

As shown in FIG. 1 to FIG. 3, in the water-cooling device 100 according to the embodiment of the present invention, a minimum distance between the liquid inlet 112 and the heat conducting member 113 is less than a minimum distance between the liquid outlet 111 and the heat conducting member 113 so that the effect of the cooling liquid flowing from the liquid inlet 112 into the water block 11 on the heat conducting member 113 is greater than the effect of the cooling liquid flowing out of the water block 11 from the liquid outlet 111 on the heat conducting member 113. Since the cooling liquid flowing out of the water block 11 from the liquid outlet 111 has passed through the heat conducting member 113 and the water pump 12, its temperature is higher than the temperature of the cooling liquid flowing into the water block 11 from the liquid inlet 111, thereby reducing the effect of the temperature of the higher-temperature cooling liquid on the heat conducting member 113.

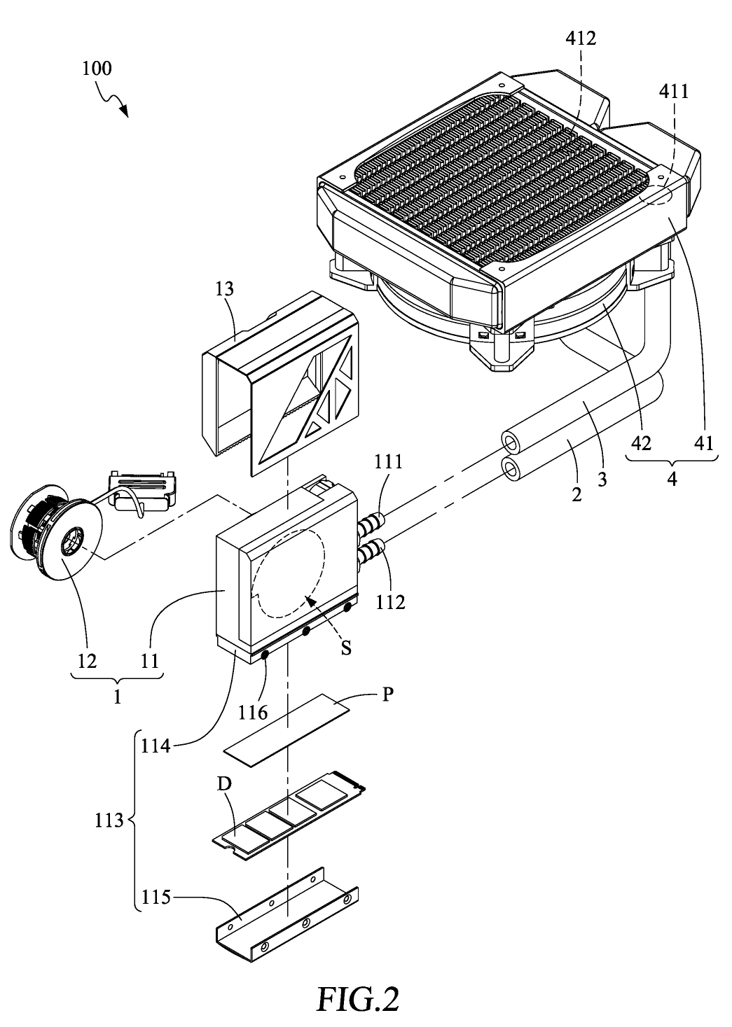

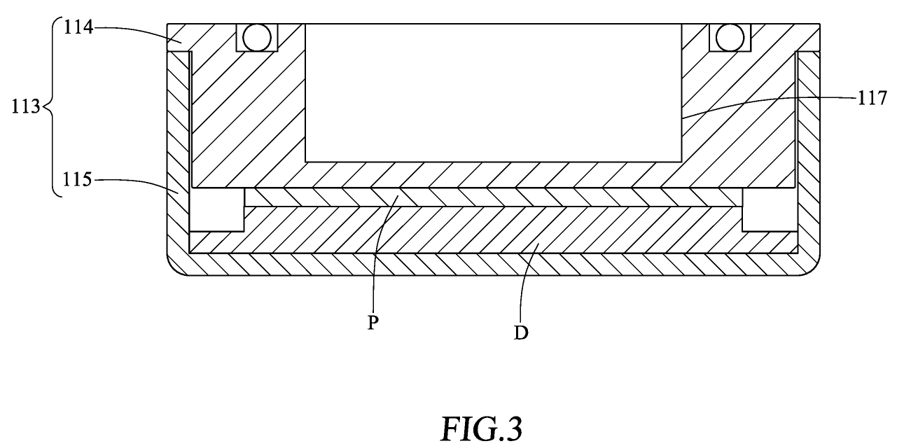

In detail, as shown in FIG. 2 and FIG. 3, the heat conducting member 113 includes a metal block 114. A thermal pad P or thermal paste is provided between the metal block 114 and the solid-state disk D to enable the heat of the solid-state disk D to be transferred to the metal block 114. The material of the metal block 114 is copper. In other embodiments, the material of the metal block 114 may be other materials of high thermal conductivity. In this embodiment, a bottom surface of the metal block 114 is a rectangular surface to match the arrangement of chips of the solid-state disk D.

As shown in FIG. 2, in the water-cooling device 100 according to the embodiment of the present invention, the heat conducting member 113 further includes a clip 115. The metal block 114 has a fixing hole 116 to which the clip 115 is fixed. The solid-state disk D is clamped between the metal block 114 and the clip 115 so that the water-cooling device 100 of the present invention and the solid-state disk D are fixed to each other.

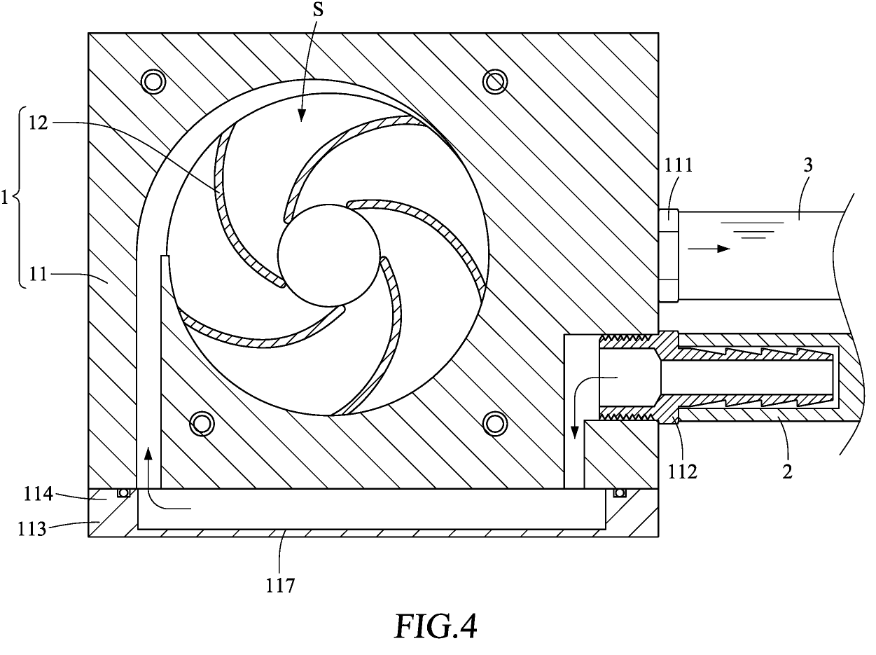

The metal block 114 may be in direct contact with the cooling liquid. In this embodiment, as shown in FIG. 3 and FIG. 4, the metal block 114 has a long groove 117. A middle section of the groove 117 is covered and both ends of the groove 117 are each formed with an opening for the cooling liquid to flows into or out of the groove 117. The arrows indicate the flow direction of the cooling liquid when driven by the water pump 12. The cooling liquid flows into the groove 117 from one end and flows out of the groove 117 from the other end. In other words, the cooling liquid of the liquid circulating sequence flows through the groove 117 which increases the contact area between the metal block 114 and the cooling liquid. In other embodiments, the metal block 114 may be replaced by a rectangular metal board.

As shown in FIG. 1 and FIG. 2, one end of the first pipe 2 is connected to the liquid inlet 112 of the water block 11, and the other end of the first pipe 2 is connected to the radiator outlet 411 of the radiator 41 of the water-cooling radiator component 4. Driven by the water pump 12, the cooling liquid in the first pipe 2 flows from the radiator outlet 411 to the liquid inlet 112. The first pipe 2 can be a hard material such as metal, or a soft material such as plastic. On the other hand, the first pipe 2 may be a light transparent material through which the user can observe the cooling liquid in the first pipe 2.

As shown in FIG. 1 and FIG. 2, one end of the second pipe 3 is connected to the liquid outlet 111 of the water block 11, and the other end of the second pipe 3 is connected to the radiator inlet 412 of the radiator 41 of the water-cooling radiator component 4. Driven by the water pump 12, the cooling liquid in the second pipe 3 flows from the liquid outlet 111 to the radiator inlet 412. The second pipe 3 may be a hard material such as metal, or a soft material such as plastic. On the other hand, the second pipe 3 may be a light transparent material through which the user can observe the cooling liquid in the second pipe 3. The material of the second pipe 3 and the first pipe 2 can be the same or different.

The water-cooling radiator component 4 has a heat radiator 41 and a fan 42. The heat radiator 41 is provided for the cooling liquid to flow through so as to transfer heat of the cooling liquid to the air. The fan 42 faces towards the heat radiator 41 to enhance the efficiency of transferring heat from the cooling liquid to the air.

The heat radiator 41 has a radiator outlet 411 and a radiator inlet 412 for the cooling liquid to flow out of and into the water block 11, respectively. The radiator outlet 411 is connected to the other end of the first pipe 2, and the radiator inlet 412 is connected to the other end of the second pipe 3.

The above description should be considered as only the discussion of the preferred embodiments of the present invention. However, a person having ordinary skill in the art may make various modifications without deviating from the present invention. Those modifications still fall within the scope of the present invention.

What is claimed is:

1. A water-cooling device for a solid-state disk, comprising:
a water-cooling component, including a water block and a water pump, the water block having a water-pump accommodating space, the water pump being disposed in the water-pump accommodating space, the water block being further provided with a liquid inlet, a liquid outlet and a heat conducting member, the heat conducting member being provided to form heat conduction with the solid-state disk to enable the water block to receive heat from the solid-state disk;
a first pipe, one end of the first pipe being connected to the liquid inlet;
a second pipe, one end of the second pipe being connected to the liquid outlet; and
a water-cooling radiator component, having a radiator inlet, a radiator outlet and a heat radiator, the radiator outlet being connected to the other end of the first pipe, and the radiator inlet being connected to the other end of the second pipe, the water pump being provided to drive cooling liquid to flow in a liquid circulating sequence of the water-cooling component, the second pipe, the water-cooling radiator component, the first pipe and the water-cooling component, the heat radiator of the water-cooling radiator component is provided to transfer heat from the cooling liquid to the air.

2. The water-cooling device as claimed in claim 1, wherein the heat conducting member includes a metal block, which is in contact with the solid-state disk so that the water block receives the heat from the solid-state disk via the metal block.

3. The water-cooling device as claimed in claim 2, wherein the heat conducting member includes a clip, the metal block has a fixing hole to which the clip is fixed, and the solid-state disk is clamped between the metal block and the clip.

4. The water-cooling device as claimed in claim 2, wherein the metal block has a groove through which the liquid of the liquid circulating sequence flows.

5. The water-cooling device as claimed in claim 1, wherein a minimum distance between the liquid inlet and the heat conducting member is less than a minimum distance between the liquid outlet and the heat conducting member.

6. The water-cooling device as claimed in claim 1, wherein the water-cooling radiator component includes a fan which faces towards the heat radiator.
